(19) United States
(12) Patent Application Publication
(10) Pub. No.: US 2006/0145703 A1
(43) Pub. Date: Jul. 6, 2006

(54) Automatic component testing

(76) Inventors: Marcus Steinbichler, Neubeuern (DE); Roman Berger, Schnaitsee (DE); Jorg Collrep, Kolbermoor (DE); Rainer Huber, Piding (DE)

Correspondence Address: ALLEMAN HALL MCCOY RUSSELL & TUTTLE LLP, 806 SW BROADWAY, SUITE 600, PORTLAND, OR, 97205-3335, US

(21) Appl. No.: 11/314,181

(22) Filed: Dec. 20, 2005

(30) Foreign Application Priority Data
Dec. 20, 2004 (DE) 10 2004 061 338.9

(51) Int. Cl. G01R 31/08; G05B 19/18; G08B 21/00

(52) U.S. Cl. 324/512; 700/56; 340/686.1

(57) ABSTRACT

A method of testing a component, wherein the component is sensed using a test sensor whose position is tested and an apparatus for the carrying out of the method.

### CROSS REFERENCE TO RELATED APPLICATIONS

This application claims priority to German Patent Application Serial No. DE 102004061338.9 filed Dec. 20, 2004, which is hereby incorporated by reference in its entirety for all purposes.

1. Field

The present disclosure relates to a method of testing a component and to an apparatus for carrying out the method.

2. Background and Summary

Different methods of testing components are already known. With the already known methods, the component structure or the component surface can be examined or tested, for example, for damage or inhomogeneities. EP-1 284 409 A1, for example, describes a shearographic test method in which different load states of the component are measured interferometrically. The different load states can be established by thermal radiation. Interferometric images are recorded in the different load states using a camera. Irregularities in the component structure can be visualized by subtraction of the interferograms. In addition to shearographic test methods, other interferometric test methods and speckle test methods are known, e.g. ESPI (electronic speckle pattern interferometry) or digital speckle photography. Further known methods of component testing are strip projection methods, laser scan methods, linear scan methods, moiré methods, white light methods (white light interferometry, grid methods), ultrasonic methods, eddy current methods, X-ray methods and thermographic methods.

A disadvantage of the already known test methods consists of the fact that only one single section of the component can be tested in a specific position of the test sensor, i.e. in an individual measurement. Complex or large components therefore have to be examined in a plurality of individual tests using a fixed test plan. In this process, it is difficult to work through the test plan without markings on the component. A precise positioning of the test sensor is furthermore only possible with difficulty since the sensor has to be positioned by hand. For this reason, the individual sections covered with individual measurements must have comparatively large overlap regions so that gap-free component testing is ensured.

Furthermore, there is the problem with the aforesaid methods that the test results of the individual measurements have to be combined to form a total test result. For this purpose, the spatial position of the test sensor has to be known for the individual measurements. Furthermore, the three-dimensional geometrical contour (3D contour) of the component must be known so that the test results can be associated with the locations in or on the component.

EP-1 284 409 A1 proposes a test sensor to solve this problem which is mechanically coupled to a spatially fixed central unit in a defined manner so that the spatial position of the test sensor relative to the central unit—and thus in the spatially fixed coordinate system—is always known. Different test positions are moved to by defined relative movements of the test sensor so that the spatial position of the test sensor can always be given precisely via the defined relative movements. However, this solution has the disadvantage that the fixed mechanical coupling of the test sensor to the central unit restricts the freedom of movement of the test sensor. It is not possible—or is only possible with a high technical effort—to position the test sensor on the component in any desired manner.

Against this background, it is the object of the present disclosure to improve the already known test methods. It is furthermore the object of the present disclosure to propose a testing system for the carrying out of the method in accordance with the present disclosure. A method and a system should in particular be proposed in which the individual measurements can be worked through without markings on the component. Furthermore, a more precise positioning of the test sensor on the component to be tested should be made possible with the method and system in accordance with the present disclosure. Furthermore, the method in accordance with the present disclosure should permit the overlap regions of different individual measurements to be kept as low as possible. Finally, it is the object of the present disclosure to propose a test method in which the spatial position of the test sensor can also be given without a mechanical coupling to a spatially fixed central unit.

In accordance with the present disclosure, the object is solved by a method in accordance with claim 1 and by an apparatus in accordance with claim 15. Advantageous aspects result from the dependent claims.

One disclosed embodiment solves the object in accordance with the present disclosure by a method of testing a component in which the component is tested using a test sensor whose position is sensed. It is possible by the sensing of the position of the test sensor to determine the spatial position of the test sensor in a spatially fixed coordinate system at any time. This determination takes place without a defined mechanical coupling of the test sensor to a spatially fixed central unit. A marking of the test positions on the component can be dispensed with by the automatic sensing of the position of the test sensor. In addition, the sensing of the position of the test sensor permits the association of the test results to the associated locations in or on the component. Furthermore, the sensing of the position of the test sensor permits the combination of the test results of individual measurements to form a total test result.

In another embodiment of the method, the sensed positions of the test sensor are documented and/or stored. This simplifies the combination of the test results of individual measurements to form a total test result. Furthermore, the association of the test results to the associated locations in or on the component is facilitated. Finally, the documentation or storage of the sensed positions of the test sensor simplifies the processing and evaluation of the test results, in particular by way of electronic data processing. In particular the electronic visualization of the test results can thus be achieved more easily.

In a further embodiment of the method, the position of the test sensor is sensed using a tracking system. A tracking system is a system with which the position of an object in space can be sensed in a contact-free manner, in particular without a defined mechanical coupling to a spatially fixed central unit. The advantage is achieved by the combination of the test sensor with a tracking system of this type that the test sensor can be moved on the component in any desired manner and its position can be sensed simultaneously without any great technical effort. The combination in accordance with the present disclosure of test sensor and tracking system thus ensures the desired freedom of movement of the test sensor.

In another embodiment, the tracking system is made as a triangulation tracking system. A tracking system of this type advantageously includes a spatially fixed base unit with at least two sensors, in particular cameras, spaced apart from one another. A further component of the triangulation tracking system is represented by at least three marks which are applied spaced apart to the object whose spatial position is to be sensed. The sensors and marks are designed such that the marks can be detected by the sensors in the base unit. The marks can be passive elements, in particular reflectors, and/or active elements, so-called actuators. Actuators of this type transmit signals which can be received by the sensors of the base unit of the triangulation tracking system. Light-emitting diodes which transmit optical signals can, for example, be used as actuators or also electromagnetic transmitters. To be able to sense the position of the object at any spatial position, at least three of the marks applied to the object must always be detectable by the base unit. It is thereby ensured that signals from at least three marks can be detected by the two spaced apart sensors of the base unit at any spatial position. The three-dimensional spatial coordinates of the at least three actuators can be determined by means of the detected signals by way of triangulation. The position of the object can thus be given in the spatially fixed coordinate system of the triangulation tracking system.

In other embodiments, a GPS tracking system, a laser tracking system or a photogrammetric tracking system can be used as the tracking system.

In an embodiment, the GPS tracking system includes at least three transmitters which are spaced apart from one another and whose spatial position in the spatially fixed coordinate system is known. The transmitters may be satellites or transmitters with a spatially fixed position. The GPS tracking system furthermore includes at least three receivers which are applied spaced apart to the object whose spatial position is to be determined, that is to the test sensor in the present case. Advantageously, at least three of the receivers attached to the test sensor can receive signals from at least three transmitters in any position of the test sensor which can be considered. The spatial position of a receiver receiving signals from at least three transmitters can be determined in accordance with known methods. If the spatial position of at least three receivers is determined in this manner—sequentially or simultaneously—the spatial position of the test sensor can be given on this basis. Alternatively, the spatial position of the test sensor can be determined using only one receiver. The receiver is then positioned at at least three points on the test sensor which are known and are spaced apart from one another. The spatial coordinates of the points at which the receiver has been positioned can then be determined in accordance with known methods.

In another embodiment, a laser tracking system includes a spatially fixed laser for the generation of a laser beam as well as a spatially fixed interferometer. The laser tracking system furthermore includes a reflector which is applied to the object whose spatial position is to be determined, that is to the test sensor in the present case. The laser beam is reflected by the reflector into the interferometer and is evaluated with the latter to determine the spatial position of the test sensor. This evaluation makes possible the determination of changes in the spacing of the reflector from the interferometer. The absolute spacing of the reflector is determined in accordance with known methods, for example by a measurement of the light transit time. In this manner, the spacing of the reflector from the interferometer is sensed using the components of laser, reflector and interferometer. On a movement of the test sensor, for example when navigating the test sensor over the component, the laser beam and the interferometer are tracked automatically in accordance with a known method so that the laser beam always hits the reflector and a reflection can always be sensed using the interferometer. The pivot movements required for the tracking of the laser beam and the interferometer are sensed by measurement of the pivot angles. The translation of the reflector on a displacement of the test sensor can be determined in three dimensions by the combination of the measured spacing change with the measured angle changes so that the absolute spatial position of the reflector can be determined in all three spatial coordinates. The spatial coordinates of at least three spaced apart points on the test sensor must be known for the determination of the spatial position of the test sensor. This can be achieved in that the reflector is moved to three points of the test sensor which are known and which are spaced apart from one another and in that the determination of the spatial coordinates of the reflector described above is carried out at each of these points. In a variant, the reflector is not moved, but is attached in a stationary manner to a known point of the test sensor. In this variant, the laser tracking system additionally includes a camera system and at least two marks which are applied spaced apart to the test sensor and which can be detected by the camera system. The marks can be elements, so-called actuators. The spatial position of the two marks can then be determined on the basis of the signals detected by the camera system by way of triangulation as with the triangulation tracking system. In this manner, the three-dimensional spatial position of the test sensor is determined by determination of the spatial coordinates of three points on the test sensor which are known and spaced apart with the help of the laser tracking system.

In another embodiment, a photogrammetric tracking system includes at least one camera. In a photogrammetric tracking system, the component to be tested with the test sensor must be photographed from at least two different positions. If the photogrammetric tracking system only includes one camera, its position must be changed to obtain images from different camera positions. If the tracking system includes a plurality of cameras, the images can be generated from different positions by the suitably positioned cameras. The photogrammetric tracking system furthermore includes at least three spatially fixed marks which remain spatially fixed during the whole measurement and whose mutual spacing is known. The at least three spatially fixed marks must be located inside the measuring field of the camera in both camera positions. The at least three spatially fixed marks serve the calibration of the photogrammetric tracking system. The at least three spatially fixed marks can advantageously be applied to points of the component to be tested whose relative spatial positions are known. In another advantageous embodiment, striking object points of the component to be tested or of the test sensor can also be used as spatially fixed marks. To determine the spatial position of the test sensor, an image of the component to be tested with the test sensor located thereon is taken with the camera from the two camera positions. The three-dimensional spatial position of the test sensor is determined by way of the known photogrammetric evaluation of the images taken.

The tracking systems described above are used to sense the position of the test sensor in accordance with various embodiments of the method in accordance with the present disclosure. In this manner, the position of the test sensor can be sensed in a contact-free manner at any time, i.e. without any physical connection between the test sensor and a spatially fixed central unit or without any fixed mechanical coupling to a spatially fixed central unit. It is thus, for example, possible to dispense with connecting the test sensor to a spatially fixed central unit via pivot arms which are hingedly connected, which are optionally telescopic and which can be adjusted in a defined manner. The method in accordance with the present disclosure therefore permits the omission of a complex and precise mechanical system for the positioning of the test sensor. The embodiment in accordance with the present disclosure permits a very free movement of the test sensor on the component to be tested.

In a further embodiment of the method, the tracking system is used to position and/or navigate the test sensor on the component. This can be achieved, for example, in that the position of the test sensor currently sensed by the tracking system is shown on a display so that the operator of the system can read off the current position of the test sensor at any time. The test sensor can thereby be brought into a desired position particularly easily. The test sensor can furthermore be navigated easily over the component in accordance with a predetermined test plan so that the test plan can be worked through in a comfortable manner.

A further embodiment of the method provides for taking a plurality of individual measurements with the test sensor to test the component. The test sensor is positioned for each of these individual measurements, for example in that the actual position sensed by the tracking system is compared with the desired nominal position. Once the desired position has been reached, the planned individual measurement is carried out. This embodiment of the method makes it possible to test larger areas of the component or to test the whole component in steps.

A point-by-point test sensor, in particular an ultrasound sensor, can be used for the method in accordance with the present disclosure. In this embodiment, larger test areas can be examined by scanning with the point-by-point test sensor.

In another embodiment, an aerial test sensor, in particular a thermographic or shearographic sensor, is used as the test sensor. An aerial individual section of the component can be tested in an individual measurement using such test sensors.

The test results determined using the test sensor are advantageously associated with the associated locations on or in the component to be tested. A spatially resolved test result can be made available with the test method in accordance with the present disclosure by this embodiment. Spatially resolved structural information on the component can, for example, be output in this manner. It can in particular be seen from such a spatially resolved test result at which points of the component the actual quality deviates from the desired quality.

In accordance with a further improvement of the method, the 3D contour data of the component are read in. The 3D contour data describe the three-dimensional geometrical contour of the component. These 3D contour data can be obtained, for example, from the CAD design data of the component. The determination of the position of the component in the spatially fixed coordinate system of the tracking system is furthermore advantageous. For this purpose, the test sensor must be positioned at a plurality of different locations on the component and the position must be sensed at every position by means of the tracking system. The position of the component in the spatially fixed coordinate system of the base unit of the tracking system can be determined on the basis of the sensed positions of the test sensor and on the basis of the relative position of the test sensor to the component defined by the geometry of the test sensor. The 3D contour data of the component and its spatial position make it possible to associate the test results determined by the test sensor with the associated locations on or in the component.

In another embodiment, the 3D contour data of the component are digitally sensed by means of a digitization system. A digitizing of this type can, for example, be necessary if the 3D contour data are not otherwise available, for example in the form of CAD design data.

The digital sensing of the 3D contour data is advantageously carried out by way of the strip projection method. The digitizing system can furthermore be advantageously combined with the test sensor to form a compact sensor unit. In other variants of the method in accordance with the present disclosure, the digitizing can also be carried out by way of the triangulation method, the linear scan method, the laser scan method (using different wavelengths), the grid method, the photogrammetric method or the ultrasound method.

In a further embodiment of the present disclosure, the testing of the component is carried out in the shearographic method. The same camera can then be used for the shearographic method and for the strip projection method. The costs of the test method can thereby be cut by a more cost favorable test apparatus.

In another advantageous embodiment of the method, the test results of individual measurements are combined to form a total test result while eliminating overlap regions. If a larger region of the component should be tested, the component is advantageously scanned in a plurality of individual measurements. In these individual measurements, respective individual test sections are obtained as the test result. To cover the whole examined region, the individual test sections must each overlap. It is advantageous to eliminate these overlap regions in the generation of a total test result from the individual measurements. This can in particular take place in the measured data processing by way of electronic data processing.

In a further advantageous embodiment of the present disclosure, the test results are visualized in an image of the component. This can in particular take place in an image generated by way of electronic data processing. The user of the method can see at which points of the component the actual quality differs from the desired quality particularly easily from an image of this type.

The present disclosure further relates to an apparatus for the carrying out of the method in accordance with the present disclosure, i.e. to an apparatus for testing a component. The apparatus in accordance with the present disclosure includes a sensor unit and a tracking system. The sensor unit is positioned and/or navigated on the component in a suitable manner for the examination of the component. The position of the sensor unit is sensed with the tracking system. The sensor unit includes a test sensor to test the component. The method in accordance with the present disclosure can be carried out using this apparatus; the component can in particular be tested while sensing the position of the test sensor.

In an advantageous embodiment, the tracking system is made as a triangulation tracking system. A tracking system of this type includes a spatially fixed base unit and marks applied spaced apart on the sensor unit. The determination of the position of the sensor unit may take place using at least three marks. The marks can be passive elements, in particular reflectors, and/or active elements, so-called actuators. Actuators of this type are fitted with means for the transmission of signals. The base unit is fitted with means for the detection of the signals starting from the marks. The base unit may have at last two spaced means of this type for the detection of signals. The means for the detection of the signals may be sensors or cameras. The sensors of the base unit may detect signals from at least three spaced apart marks for the sensing of the position of the sensor unit using the triangulation tracking system.

In other advantageous embodiments, the tracking system can be made as a GPS tracking system, as a laser tracking system or as a photogrammetric tracking system.

A shearographic sensor, a thermographic sensor or an ultrasound sensor may be used as the test sensor.

The load unit required for the shearographic sensor is advantageously integrated into the sensor unit. A heat radiator, an ultrasound exciter or a vacuum chamber can, for example, be used as the load unit.

The apparatus for the testing of a component advantageously includes a digitizing system for the determination of the 3D contour data of the component. This embodiment makes it possible to sense the 3D contour data of the component simultaneously with the testing of the component. This is in particular advantageous when the 3D contour data are not otherwise available. It is furthermore advantageous for the digitizing system to be integrated into the sensor unit. The apparatus in accordance with the present disclosure can thereby be made particularly compact so that they only consist of two main elements, namely the base unit of the tracking system and the sensor unit. This simplifies the operation.

In a further embodiment, a strip projection sensor is used as the digitizing system which includes a strip projector, a camera and a corresponding measured data processing system. It is particularly advantageous for the shearographic sensor and the strip projection sensor to use the same camera. The apparatus in accordance with the present disclosure can then be manufactured in a particularly cost favorable manner.

The sensor unit advantageously includes a navigation aid coupled to the tracking system. The sensor unit can be navigated over the surface of the component using this navigation aid so that the sensor unit can be positioned at desired positions particularly easily. The navigation aid can be realized, for example, in that the current position of the sensor unit respectively sensed by the tracking system is shown on a display. The currently sensed position can be shown graphically or numerically in spatial coordinates on the display. In another embodiment of the navigation aid, the deviation of the currently sensed actual positions is given by the desired nominal position of the sensor unit.

A further improvement of the apparatus in accordance with the present disclosure includes a data processing unit which associates the test results of the test sensor with the digitized 3D contour data of the component. The individual test sections can also be combined to form a total test result with this data processing. The elimination of the overlap regions can likewise be achieved by the data processing unit. Finally, the total test result can be visualized for the user with the data processing.

Embodiments of the present disclosure will be explained with reference to FIGS. 1 to 11.

### BRIEF DESCRIPTION OF THE FIGURES

FIG. 1 is a schematic representation of an apparatus in accordance with the present disclosure for the carrying out of the method in accordance with the present disclosure with a point-by-point test sensor and a triangulation tracking system.

FIG. 2 is a schematic representation of an apparatus in accordance with the present disclosure for the carrying out of the method in accordance with the present disclosure with an aerial test sensor and a triangulation tracking system.

FIG. 3 is an illustration of an individual section of the component tested in an individual measurement.

FIG. 4 is an illustration of a plurality of individual sections tested in individual measurements and their overlap regions.

FIG. 5 is an illustration of the combination of the individual sections to form a total test image while eliminating the overlap regions.

FIG. 6 is a sensor unit in accordance with the present disclosure with a shearographic sensor and an integrated digitizing system (strip projection sensor).

FIG. 7 is a sensor unit in accordance with the present disclosure with a shearographic sensor and a strip projection sensor with a common camera.

FIG. 8 is an illustration of the sensor unit shown in FIG. 7 in a shearographic measurement.

FIG. 9 is a schematic representation of an apparatus in accordance with the present disclosure for the carrying out of the method in accordance with the present disclosure with an aerial test sensor and a GPS tracking system.

FIG. 10 is a schematic representation of an apparatus in accordance with the present disclosure for the carrying out of the method in accordance with the present disclosure with an aerial test sensor and a laser tracking system;

FIG. 11 is a schematic representation of an apparatus in accordance with the present disclosure for the carrying out of the method in accordance with the present disclosure with an aerial test sensor and a photogrammetric tracking system.

### DETAILED DESCRIPTION

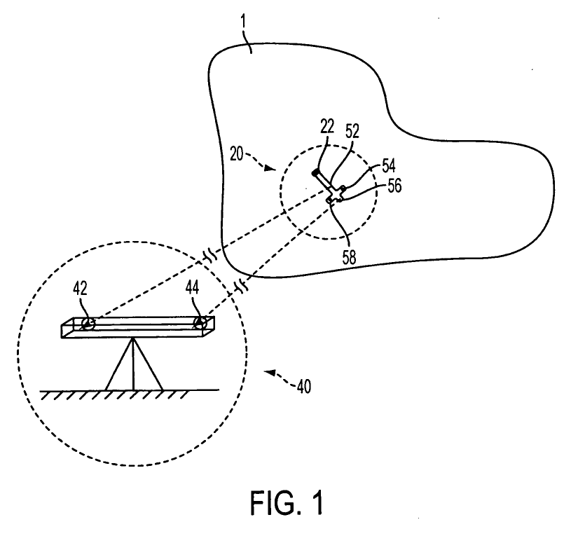

FIG. 1 shows a component 1 with a sensor unit 20 positioned thereon (in the broken-line circle). A point-by-point test sensor 22 is integrated into the sensor unit 20. It can be an ultrasound sensor. Spaced apart actuators 52, 54, 56, 58 of the triangulation tracking system are applied to the sensor unit 20. Furthermore, the spatially fixed base unit 40 of the triangulation tracking system is shown (in the broken-line circle) in FIG. 1. The base unit 40 of the triangulation tracking system includes two cameras 42 and 44 spaced apart from one another. The cameras 42 and 44 receive the signals transmitted by the actuators 52, 54, 56, 58. The position of the sensor unit 20 and thus the position of the test sensor 22 in the spatially fixed coordinate system of the base unit 40 of the triangulation tracking system can be determined from the signals received, from the known spatial position of the cameras and from the known relative position of the actuators on the sensor unit.

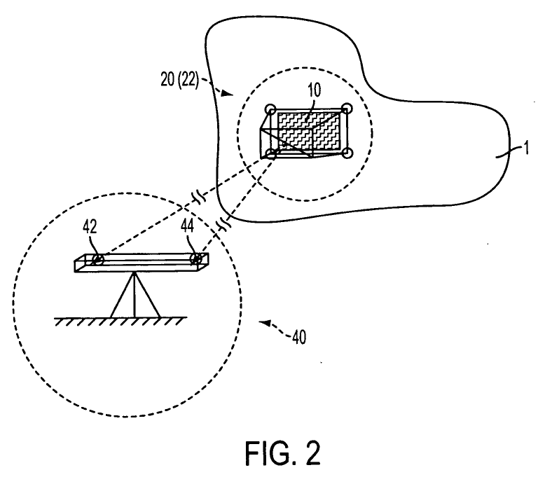

FIG. 2 shows a component 1 with a sensor unit 20 positioned thereon with an aerial test sensor 22. It can be a shearographic sensor or a thermographic sensor. The individual section 10 of the component 1 can be tested with the aerial test sensor 22 in an individual measurement. Actuators (not shown in FIG. 1) of the triangulation tracking system are applied to the sensor unit 20. The base unit 40 of the triangulation tracking system into which the spaced apart cameras 42 and 44 are integrated is likewise shown in FIG. 2.

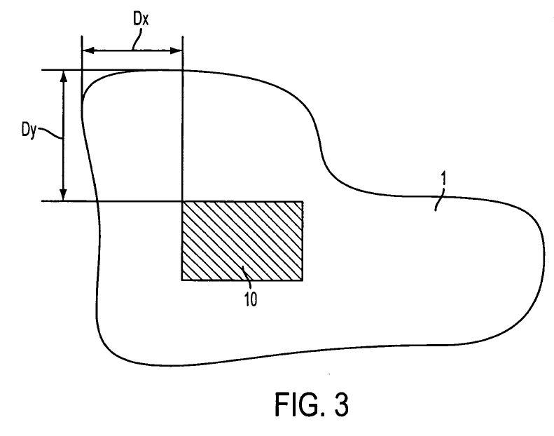

FIG. 3 illustrates the individual section 10 of a component 1 tested in an individual measurement with an aerial test sensor 22. The test results for the individual section 10 can be associated with the associated locations on or in the component 1 in accordance with the method in accordance with the present disclosure via the relative coordinates Dx and Dy.

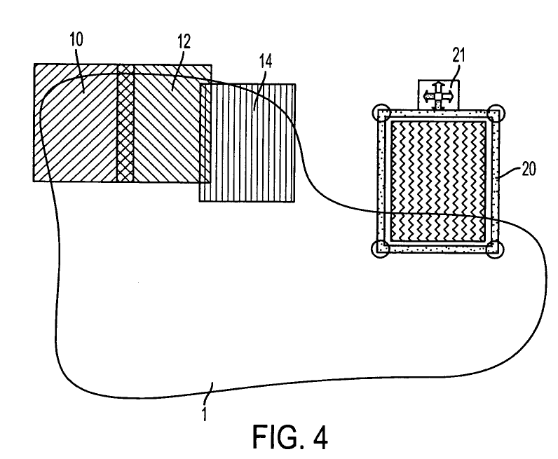

FIG. 4 shows a plurality of individual sections 10, 12 and 14 of the component 1 tested in individual measurements. The individual sections 10, 12 and 14 have overlap regions which can be eliminated on the combination of the individual measurements to form a total test result. A schematic representation of a sensor unit 20 is shown with a navigation aid 21 in the right hand part of FIG. 4. This navigation aid 21 shows on a display with arrows the direction in which the sensor 20 has to be moved so that the current actual position can be brought into coincidence with the desired nominal position.

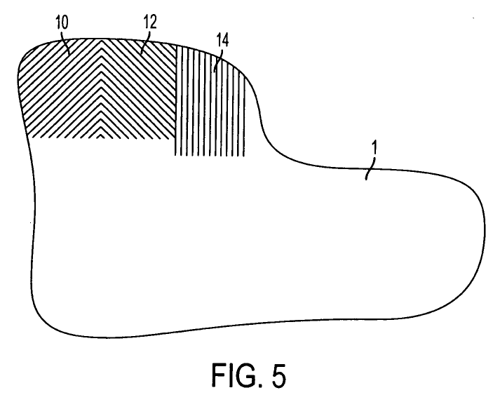

FIG. 5 illustrates the individual measurements of the individual sections 10, 12 and 14 combined to form a total test result. The overlap regions shown in FIG. 4 were eliminated in the combination.

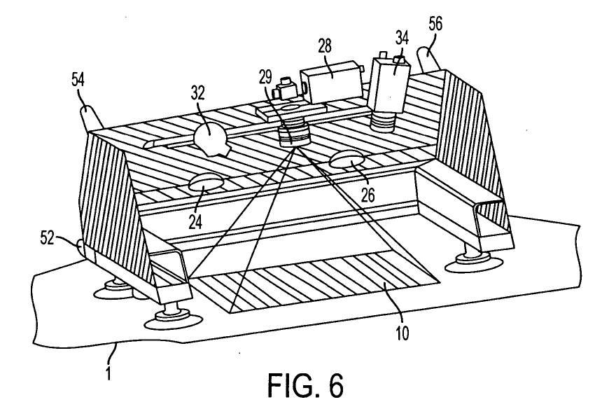

FIG. 6 shows a sensor unit 20 in accordance with the present disclosure with a shearographic sensor as the test sensor 22 and a strip projection sensor as the digitizing system. The individual section 10 of the component 1 is tested in the representation in FIG. 6. The actuators 52, 54, 56 are applied to the sensor unit 20. Further actuators are not shown in FIG. 6. The load unit of the shearographic sensor is realized by heat radiators 24 and 26. These heat radiators 24 and 26 are integrated into the sensor unit 20. The shearographic sensor furthermore includes an interferometric camera 28 with a lens 29. A digitizing system in the form of a strip projection sensor is integrated into the sensor unit 20 in FIG. 6. The strip projection sensor includes the strip projector 32 and the digitizing camera 34.

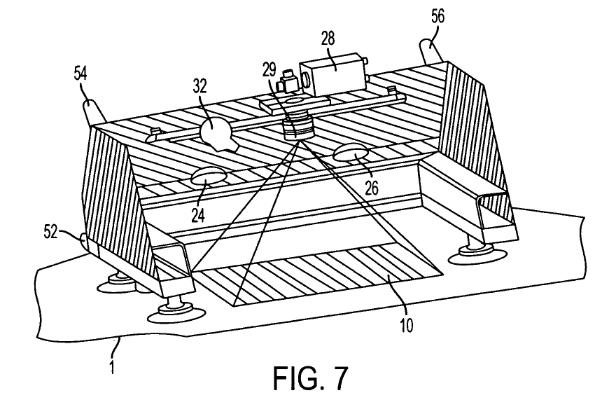

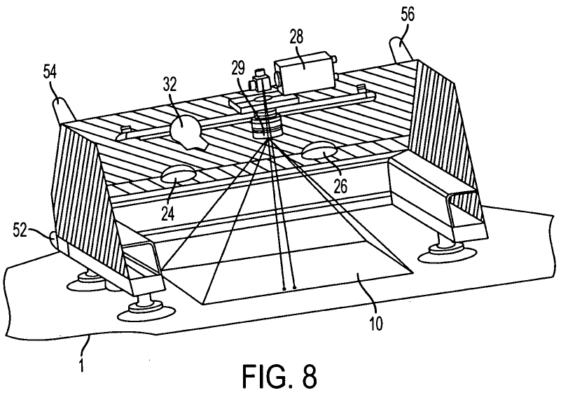

FIGS. 7 and 8 show a further embodiment of a sensor unit 20 in accordance with the present disclosure. This sensor unit also includes a shearographic sensor as the test sensor 22 and a strip projection sensor as the digitizing system. The shearographic sensor and the strip project sensor use the same camera 28 with the attached lens 29 in the embodiment shown in FIGS. 7 and 8. The sensor unit 20 can be manufactured more cost effectively by the use of a common camera for the shearographic sensor and the strip projection sensor. FIG. 7 shows the sensor unit 20 in digitizing operation; FIG. 8 in a shearographic measurement.

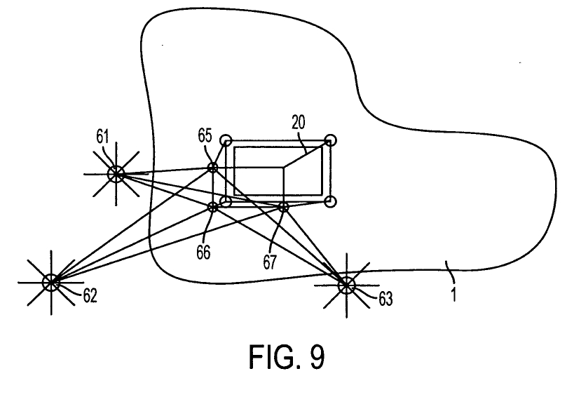

FIG. 9 shows an apparatus in accordance with the present disclosure with a GPS tracking system. The transmitters 61, 62 and 63 are spaced apart from one another and positioned in a spatially fixed manner. The position of the transmitters in the spatially fixed coordinate system is known. The receivers 65, 66 and 67 are spaced apart on the sensor unit 20. In the situation shown in FIG. 9, each of the receivers 65, 66 and 67 receive signals from the three transmitters 61, 62 and 63. The coordinates of all three receivers in the spatially fixed coordinate system can be determined on this basis. The spatial position of the sensor unit 20 can be determined from the spatial coordinates of the three receivers 65, 66 and 67.

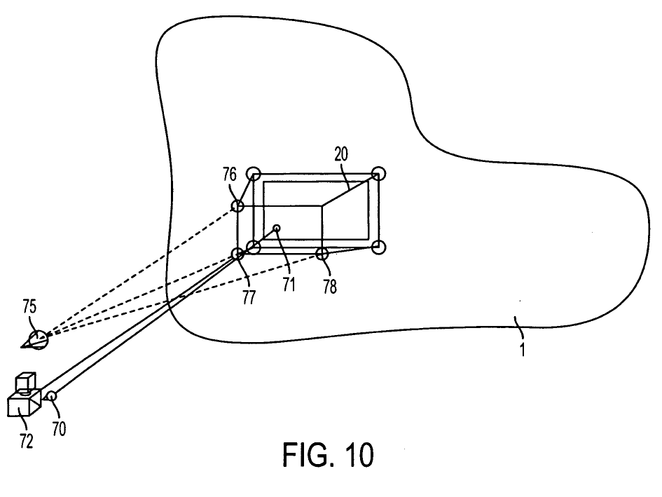

FIG. 10 shows an apparatus in accordance with the present disclosure with a laser tracking system. The laser beam transmitted by the spatially fixed laser 70 is reflected by the reflector 71 attached to the sensor unit 20 into the spatially fixed interferometer 72 and is evaluated with said interferometer. This permits the determination of the change in the distance of the reflector 71 in the navigating of the sensor unit 20 over the component 1. On the navigating of the sensor unit 20 over the component 1, the laser 70 and the interferometer 72 are tracked such that the laser 70 always hits the reflector 71 and the reflection can always be sensed by the interferometer 72. The pivot angles required for the tracking of the laser 70 and the interferometer 72 are sensed by the laser tracking system. The three spatial coordinates of the reflector 71 can be determined from the distance of the reflector 71 and from the pivot angles. The laser tracking system shown in FIG. 10 furthermore includes a camera unit 75 and the actuators 76, 77 and 78. The actuators 76, 77 and 78 are sensed using the camera unit 75. The spatial position of the actuators 76, 77 and 78 is determined by way of triangulation. The spatial position of the sensor unit 20 can be determined from the spatial position of the reflector 71 and the spatial position of the actuators 76, 77 and 78 obtained by way of triangulation.

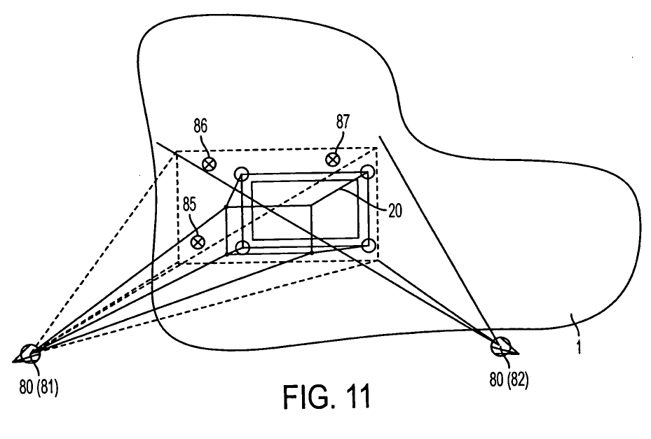

FIG. 11 shows an apparatus in accordance with the present disclosure with a photogrammetric tracking system. The photogrammetric tracking system shown includes a camera 80 which is positioned at two different camera positions 81 and 82. Three spatially fixed marks 85, 86 and 87 which are spaced apart from one another and whose mutual spacing is known are located on the component 1. The spatially fixed marks 85, 86 and 87 are located in the measuring field of the camera 80 in both camera positions 81 and 82. The three spatially fixed marks 85, 86 and 87 serve the calibration of the photogrammetric tracking system. They supply the reference coordinate system for the photogrammetric evaluation of the images taken with the camera. Images of the component 1 with the sensor unit 20 located thereon are taken from the camera positions 81 and 82. The spatial position of the sensor unit 20 is determined from these in accordance with known photogrammetric evaluation methods.

A number of advantages are achieved with the disclosed embodiments. The position of the test sensor in the spatially fixed coordinate system can be sensed in a non-contact manner and without any physical connection to a spatially fixed base unit at any time. A mechanical coupling of the test sensor to the base unit can thereby also be dispensed with. This increases the motion capability of the test sensor. Digitizing for the obtaining of the 3D contour data can furthermore take place simultaneously with the testing of the component. The position of the component to be tested in space can also be determined by the tracking system by means of a plurality of position determinations. The association of the measurement results obtained with the method in accordance with the present disclosure and those obtained with the apparatus in accordance with the present disclosure makes it possible to associate the test results to the associated locations on or in the component and to visualize them. The spatial position of structural defects of the component can thus be visualized easily. In this manner, large and complex components, for example, airplane parts, plant parts or production parts, can be tested particularly easily and reliably with the method in accordance with the present disclosure and the apparatus in accordance with the present disclosure. The inspection of components can moreover be automated using the present disclosure.

1. A method of testing a component, wherein the component is tested using a test sensor whose position is sensed.

2. The method according to claim 1, wherein the sensed positions of the test sensor are documented and/or stored.

3. The method according to claim 1, wherein the position of the test sensor is sensed using a tracking system.

4. The method according to claim 3, wherein a triangulation tracking system is used for the sensing of the position of the test sensor which includes marks applied to the test sensor and a base unit with sensors, with the marks being detected with the sensors of the base unit to sense the position of the test sensor.

5. The method according to claim 4, wherein actuators are used as marks and signals are transmitted by the actuators attached to the test sensor for the sensing of the position of the test sensor, said signals being received by the sensors of the base unit.

6. The method according to claim 3, wherein a GPS tracking system is used as the tracking system.

7. The method according to claim 3, wherein a laser tracking system is used as the tracking system.

8. The method according to claim 3, wherein a photogrammetric tracking system is used as the tracking system.

9. The method according to claim 3, wherein the tracking system is used for the positioning and/or navigating of the test sensor on the component.

10. The method according to claim 9, wherein a plurality of individual measurements are carried out with the test sensor for the testing of the component, with the test sensor being positioned for the respective individual measurement and an individual measurement being carried out at the respective positions.

11. The method according to claim 1, wherein the component is tested using an ultrasound point-by-point test sensor.

12. The method according to claim 1, wherein the component is tested using a thermographic or shearographic aerial test sensor, with the aerial test sensor testing an individual section of the component in an individual measurement.

13. The method according to claim 1, wherein the test results determined by the test sensor are associated with the associated locations on or in the component to be tested.

14. The method according to claim 13, wherein the 3D contour data of the component are read in; and wherein the spatial position of the component is determined from a plurality of positions sensed by the tracking system.

15. The method according to claim 13, wherein the 3D contour data of the component are sensed by means of a digitizing system.

16. The method according to claim 15, wherein the digital sensing of the 3D contour data takes place by way of the strip projection method.

17. The method according to claim 16, wherein the testing of the component is carried out by way of the shearographic method, with the same camera being used for the shearographic method and for the strip projection method.

18. The method according to claim 9, wherein the test results of individual sections of the component inspected in individual measurements are combined to form a total test result while eliminating overlap regions.

19. The method according to claim 1, wherein the test results are visualized in an image of the component.

20. An apparatus for the inspection of a component comprising a sensor unit and a tracking system for the sensing of the position of the sensor unit, with the sensor unit including a test sensor for the testing of the component.

21. The apparatus according to claim 20, wherein the tracking system is made as a triangulation tracking system which has a base unit and marks fixedly connected to the sensor unit, with the base unit being fitted with means for the detection of the marks.

22. The apparatus according to claim 21, wherein the marks are made as actuators, with the actuators being fitted with means for the transmission of signals and the base unit being fitted with means for the reception of the signals transmitted by the actuators.

23. The apparatus according to claim 20, wherein the tracking system is made as a GPS tracking system.

24. The apparatus according to claim 20, wherein the tracking system is made as a laser tracking system.

25. The apparatus according to claim 20, wherein the tracking system is made as a photogrammetric tracking system.

26. The apparatus according to claim 20, wherein the test sensor is designed as an ultrasound sensor, a thermographic sensor or as an interferometric sensor, in particular as a shearographic sensor or as an ESPI (electronic speckle pattern interferometry) sensor.

27. The apparatus according to claim 26, comprising a shearographic sensor, wherein the load unit of the shearographic sensor is integrated into the sensor unit.

28. The apparatus according to claim 20, wherein the apparatus has a digitizing system for the sensing of the 3D contour data of the component.

29. The apparatus according to claim 28, wherein the digitizing system is integrated into the sensor unit.

30. The apparatus according to claim 28, wherein the digitizing system is made as a strip projection sensor comprising a strip projector and at least one camera.

31. The apparatus according to claim 20, wherein the sensor unit has a navigation aid coupled to the tracking system for the navigation of the sensor unit over the surface of the component.

32. The apparatus according to claim 20, wherein the apparatus has a data processing unit which associates the test results of the test sensor to the 3D contour data of the component, combines test results of individual sections of the component to form a total test result and/or visualizes the test result.
